(19) United States
(12) Patent Application Publication
(10) Pub. No.: US 2025/0212608 A1
(43) Pub. Date: Jun. 26, 2025

(54) DISPLAY PANEL, METHOD FOR PREPARING THE SAME, AND DISPLAY DEVICE

(71) Applicants: HEFEI VISIONOX TECHNOLOGY CO., LTD., Hefei (CN); KUNSHAN GO-VISIONOX OPTO-ELECTRONICS CO., LTD., Kunshan (CN)

(72) Inventors: Bo RAO, Hefei (CN); Chung-Chun Lee, Hefei (CN); Xiaoxi Sun, Hefei (CN); Yongqiang Du, Hefei (CN); Xuejing Zhu, Hefei (CN); Liusong Ni, Hefei (CN); Yuan Yao, Hefei (CN)

(73) Assignees: HEFEI VISIONOX TECHNOLOGY CO., LTD., Hefei (CN); KUNSHAN GO-VISIONOX OPTO-ELECTRONICS CO., LTD., Kunshan (CN)

(21) Appl. No.: 18/661,449

(22) Filed: May 10, 2024

(30) Foreign Application Priority Data
Dec. 25, 2023 (CN) 202311812755.7

(51) Int. Cl. H10K 59/122; H10K 59/40

(52) U.S. Cl. CPC H10K 59/122; H10K 59/40

(57) ABSTRACT

A display panel, a method for preparing the same, and a display device. The display panel includes a substrate, a partition structure, a first structure, and a light-emitting functional layer. The substrate includes a touch-control line and a planarization layer covering the touch-control line. The partition structure is disposed on a side of the planarization layer. The partition structure defines partition apertures and first annular grooves. The first structure is disposed within the first annular groove. The first structure is electrically insulated from the partition structure and electrically connected to the touch-control line. The light-emitting functional layer is disposed on the side of the planarization layer. The light-emitting functional layer includes light-emitting structures disposed within the plurality of partition apertures.

### CROSS-REFERENCE TO RELATED APPLICATIONS

This application claims priority to Chinese Patent Application No. 202311812755.7, entitled “DISPLAY PANEL, METHOD FOR PREPARING THE SAME, AND DISPLAY DEVICE” filed on Dec. 25, 2023, the content of which is hereby incorporated herein in its entirety by reference.

### TECHNICAL FIELD

The present application relates to the field of display technology, and particularly relates to display panels, methods for preparing the same, and display devices.

### BACKGROUND

Organic light emitting diode (OLED) display panels are a focal point in display panel research. Compared with liquid crystal display panels, OLED display panels offer advantages including low energy consumption, low cost, self-luminosity, wide viewing angles, and rapid response.

However, current OLED display panels which incorporate on-cell touch-control functionality still face challenges such as high costs and increased thickness.

### SUMMARY

In view of the above, there is a need to provide a display panel, a method for preparing the same, and a display device.

In a first aspect, an embodiment of the present application provides a display panel including:
a substrate, including at least one touch-control line and a planarization layer covering the touch-control line;
a partition structure, disposed on a side of the planarization layer, the partition structure defining a plurality of partition apertures and a plurality of first annular grooves;
at least one first structure disposed within at least one of the plurality of first annular grooves, the first structure being electrically insulated from the partition structure and electrically connected to the touch-control line; and
a light-emitting functional layer disposed on the side of the planarization layer, the light-emitting functional layer including a plurality of light-emitting structures disposed within the plurality of partition apertures.

In a second aspect, an embodiment of the present application provides a display panel, including:
a substrate;
a light-emitting functional layer disposed on a side of the substrate, the light-emitting functional layer including a plurality of light-emitting structures;
a partition structure, disposed on the side of the substrate, the partition structure defining a plurality of partition apertures and a plurality of first annular grooves; and
at least one first structure disposed within at least one of the plurality of first annular grooves, the first structure being configured to be electrically connected to a touch-control signal and electrically insulated from the partition structure.

The partition structure separates adjacent light-emitting structures, and the light-emitting structures are disposed within the partition apertures.

In a third aspect, an embodiment of the present application provides a display panel, including:
a substrate;
a partition functional layer disposed on a side of the substrate, the partition functional layer including a plurality of first annular grooves, a partition structure, and at least one first structure, the partition structure and the first structure being located at opposite sides of the first annular groove, the partition structure defining a plurality of partition apertures, the at least one first structure being disposed within at least one of the first annular grooves, and configured to be electrically connected to a touch-control signal and electrically insulated from the partition structure; and
a light-emitting functional layer disposed on the side of the substrate, the light-emitting functional layer including a plurality of light-emitting structures disposed within the partition apertures.

In a fourth aspect, an embodiment of the present application provides a display panel, including:
a substrate;
a partition structure disposed on a side of the substrate, the partition structure defining a plurality of partition apertures and a plurality of first annular grooves;
at least one first structure and at least one protecting ring, at least one of the first annular grooves encircling the first structure and the protecting ring, the first structure being configured to be electrically connected to a touch-control signal, the protecting ring being configured to be electrically connected to a protecting signal, the protecting ring being disposed around the first structure, and being spaced from the first structure, the protecting ring being electrically insulated from the first structure and the partition structure; and
a light-emitting functional layer disposed on the side of the substrate and including a plurality of light-emitting structures, the partition structure separating adjacent light-emitting structures, the light-emitting structures being disposed within the partition apertures.

In a fifth aspect, an embodiment of the present application provides a method for preparing a display panel, including:
providing a substrate including touch-control line and a planarization layer covering the touch-control line;
forming a partition structure and at least one first structure on the planarization layer, the partition structure being formed on a side of the planarization layer, the partition structure defining a plurality of partition apertures and a plurality of first annular grooves, the at least one first structure being formed within at least one of the plurality of first annular grooves, electrically insulated from the partition structure, and electrically connected to the touch-control line; and
forming a plurality of light-emitting structures on the planarization layer within the partition apertures.

In a sixth aspect, an embodiment of the present application provides a display device including the display panel described in any one of the first, second, third, fourth, and fifth aspect.

### BRIEF DESCRIPTION OF THE DRAWINGS

The drawings to be used in the description of the embodiments of the present application or the conventional art will be described briefly in order to more clearly illustrate the technical solutions in the embodiments or in the conventional art. Obviously, the drawings described below are some embodiments of the present application, and other drawings can also be obtained by those of ordinary skill in the art based on the following drawings without creative work.

FIG. 1 is a schematic sectional view of a display panel according to an embodiment of the present application.

FIG. 2 is a schematic top view of the display panel in FIG. 1.

FIG. 3 is a schematic sectional view of a display panel according to another embodiment of the present application.

FIG. 4 is a schematic sectional view of a display panel according to yet another embodiment of the present application.

FIG. 5 is a schematic top view of the display panel in FIG. 4.

FIG. 6 is an enlarged schematic view of area A in FIG. 5.

FIG. 7 is a schematic sectional view of a display panel according to yet another embodiment of the present application.

FIG. 8 is a schematic top view of the display panel in FIG. 7.

FIG. 9 is a schematic sectional view of a display panel according to yet another embodiment of the present application.

FIG. 10 is a schematic sectional view of a display panel according to yet another embodiment of the present application.

FIG. 11 shows a flowchart of a method for preparing a display panel according to an embodiment of the present application.

FIG. 12 is a schematic view of a display device according to an embodiment of the present application.

Reference signs in the drawings:

### DETAILED DESCRIPTION

In order to facilitate the understanding of the present application, the present application will be comprehensively described with reference to the drawings. Embodiments of the application are shown in the accompanying drawings. However, the present application can be implemented in various forms and therefore is not limited to the embodiments described herein. On the contrary, the purpose of providing these embodiments is to make the present application to be understood more thoroughly and comprehensively.

In the present application, an element, when referred to as being “fixed” or “connected” to another element, may be directly fixed or connected to the other element or via an intermediate element. Such terms as “vertical”, “horizontal”, “left”, “right” and the like used herein are for illustration only.

In the present application, spatial terms such as “upper” and “lower” are defined with reference to the accompanying drawings. Therefore, “upper” and “lower” can be interchangeably used. When a layer is referred to as being “above” another layer, the layer can be directly formed on the other layer, or there may be an intervening layer. Thus, when a layer is referred to as being located “directly on” another layer, there is no intervening layer inserted therebetween.

In the drawings, for clear illustration, sizes of layers and regions may be exaggerated. When a layer or a component is described as being “on” another layer or substrate, the layer or component can be directly disposed on the other layer or substrate, or there may be an intervening layer. Additionally, when a layer is described as being “between” two layers, the layer can be the only layer between the two layers, or there may be one or more intervening layers. Furthermore, the same reference signs always denote the same elements.

Use of ordinal terms such as “first”, “second”, etc., to modify an element does not by itself connote any priority, precedence, or order of one element over another or the temporal order in which acts of a method are performed. Rather, unless specifically stated otherwise, such ordinal terms are used merely as labels to distinguish one element having a certain name from another element having a same name. Additionally, it can be understood that expressions in singular forms are intended to include their plural forms as well, unless the singular forms have different meanings in context. Moreover, the terms “include”, “comprise”, and “have” indicate the presence of the stated features or components but do not preclude the presence or addition of one or more other features or components.

Unless defined otherwise, all technical and scientific terms used herein have the same meaning as commonly understood by those skilled in the art of the present application. The terms used in the specification of the present application are for the purpose of describing exemplary embodiments only and are not intended to limit the present application. The term “and/or” as used herein refers to any and all combinations of one or more listed items.

Furthermore, the drawings are not drawn to 1:1 scale, and the relative sizes of components are shown in the drawings for illustration only.

In related art of OLED display panels, a partition structure serves as a deposition limit and an encapsulation limit for a light-emitting structure. During deposition, a light-emitting layer and a cathode of the light-emitting structure are partitioned by the partition structure, and the formed cathodes are electrically connected through the partition structure, facilitating the manufacture of the OLED display panels and reducing the thickness. However, regarding to OLED display panels which incorporate on-cell touch-control functionality in the related art, at least four mask etching steps are required in manufacture, posing technical challenges such as increased costs and thickness of the layer stack, thus resulting in increased costs and thickness of the OLED display panels.

In view of the above, embodiments of the present application provide a display panel, a method for preparing the same, and a display device, wherein a first structure is disposed in a first annular groove defined by a partition structure, and thus the first structure is disposed in the same layer with the partition structure. In addition, the first structure is electrically connected to a touch-control line, and thus the first structure function as a touch-control structure. Thus, compared with the four mask etching steps for incorporating on-cell touch-control functionality in related art, the embodiments of the present application enable the partition structure and the first structure to be fabricated in a single mask etching step, achieving both partitioning effect and in-cell self-capacitance touch-control. Accordingly, the manufacturing costs and thickness are both reduced while displaying and touch-control effects are ensured.

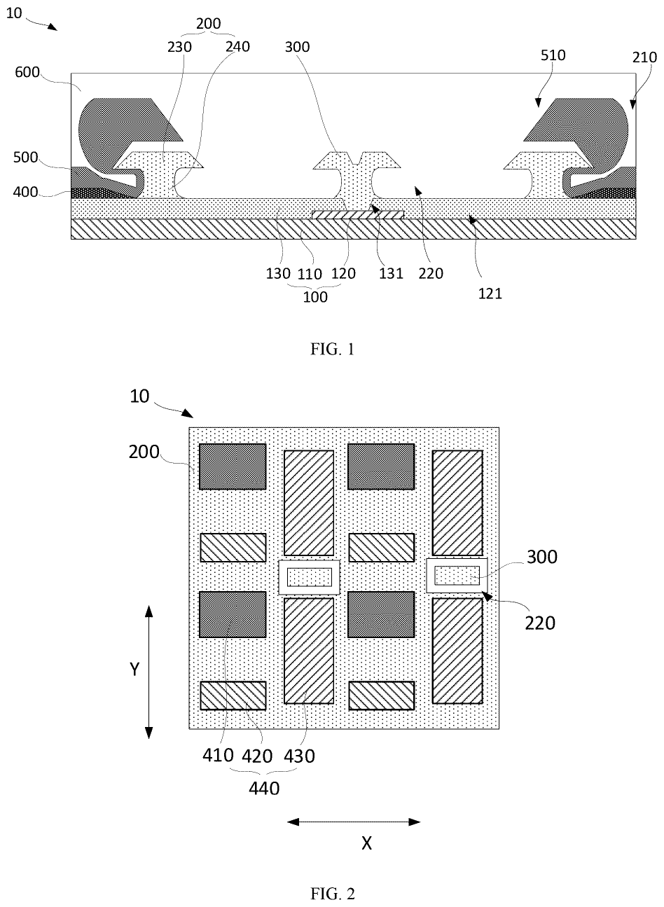

In a first aspect, referring to FIGS. 1 and 2, an embodiment of the present application provides a display panel 10. The display panel 10 includes a substrate 100, a partition structure 200, at least one first structure 300, and a light-emitting functional layer. The substrate 100 includes at least one touch-control line 120 and a planarization layer 130. The planarization layer 130 covers the touch-control line 120. The partition structure 200 is disposed on a side of the planarization layer 130. The partition structure 200 defines a plurality of partition apertures 210 and a plurality of first annular grooves 220. The first structure 300 is disposed within the first annular groove 220. The first structure 300 is electrically insulated from the partition structure 200 and electrically connected to the touch-control line 120. The light-emitting functional layer is disposed on the side of the planarization layer 130. The light-emitting functional layer includes a plurality of light-emitting structures 400 disposed within the partition apertures 210.

In some embodiments, the substrate 100 further includes an array substrate 110. The array substrate 110 includes a driving circuit array. The touch-control line 120 and the planarization layer 130 are disposed on the array substrate 110. The partition structure 200 can have a grid shape, or include a plurality of annular structures, etc., separating adjacent light-emitting structures 400. The light-emitting structures 400 can include a plurality of first light-emitting structures 410 emitting red light, a plurality of second light-emitting structures 420 emitting blue light, and a plurality of third light-emitting structures 430 emitting green light. The first, second, and third light-emitting structures 410, 420, 430 can be alternately distributed. Each light-emitting structure 400 can include an anode, a light-emitting layer, and a cathode. The anode and cathode can be made of at least one of indium tin oxide or indium zinc oxide, and the light-emitting layer can be an organic layer. The driving circuit array on the substrate 100 is electrically connected to the anode for controlling the driving voltage applied between the anode and cathode, allowing the light-emitting structure 400 to emit light, and allowing the display panel 10 to perform the displaying function.

In some embodiments, the display panel 10 further includes a first encapsulation layer 500 and a second encapsulation layer 600. The first encapsulation layer 500 is configured to individually encapsulate the first light-emitting structure 410, the second light-emitting structure 420, or the third light-emitting structure 430, so that the corresponding light-emitting structures 400 are retained during etching processes. However, after the etching processes, a cavity may be formed between the first encapsulation layer 500 and the top of the partition structure 200. To avoid collapse, before forming the second encapsulation layer 600, a photolithography aperture 510 can be formed in the first encapsulation layer 500 corresponding to the region where the partition structure 200 is located. The combination of the first encapsulation layer 500 and the second encapsulation layer 600 ensures the encapsulation effect of the display panel 10, thus avoiding water and oxygen infiltrations.

In the display panel 10 provided by the embodiments of the present application, the partition structure 200 defines the first annular grooves 220, the first structure 300 is disposed within the first annular groove 220, and the first structure 300 is electrically insulated from the partition structure 200 and electrically connected to the touch-control line 120. As such, the partition structure 200 and the first structure 300 can be fabricated in a single mask etching step, and the first structure 300 can function as a touch-control structure. Thus, in-cell self-capacitance touch-control can be achieved by a user touching the area where the first structure 300 is located, thereby allowing a signal to be transmitted through the touch-control line 120. Accordingly, the in-cell self-capacitance touch-control can be realized through the first structure 300 without a separate touch-control layer, reducing the manufacturing costs and the thickness of the display panel 10. Moreover, the light-emitting structures 400 are located within the partition apertures 210, and the partition apertures 210 and the first annular grooves 220 are defined by the partition structure 200. Therefore the presence of the first structure 300 does not affect the pixel aperture ratio of the display panel 10, thus ensuring the displaying performance. The related art of the partition structure is described in the international patent application No. PCT/CN2023/134518 and Chinese patent applications Nos. 202310759370.2, 202310740412.8, 202310707209.0, and 202311346196.5, which are all incorporated herein by reference in their entireties.

In the embodiments of the present application, the preparation of the partition structure 200 and the first structure 300 can be integrated in one mask etching step, and thus both the first structure 300 for touch-control and the partition structure 200 for separating adjacent light-emitting structures 400 are simultaneously fabricated. Therefore, the number of layers in the display panel 10 is reduced, and the product thickness is reduced. Additionally, the partition apertures 210 ensure the area of the light-emitting structures 400, thereby ensuring the pixel aperture ratio of the display panel 10.

In some embodiments, referring to FIGS. 1 and 2, the planarization layer 130 includes a plurality of first through holes 131, and each first through hole 131 extends through the planarization layer 130, exposing the touch-control line 120 through the first through hole 131. The first structure 300 is in contact with the touch-control line 120 exposed from the first through hole 131, thereby achieving an electrical connection between the first structure 300 and the touch-control line 120.

In some embodiments, the first structure 300 is made of a metal material. The metal material can have a relatively low electrical resistance, and the material of the first structure 300 can be the same as the material of the touch-control line 120.

In some embodiments, the material of the first structure 300 can be selected from the group consisting of copper, silver, gold, molybdenum, aluminum, titanium, and any combination thereof.

The mask for preparing the planarization layer 130 only needs to be provided with openings, so as to form the first through holes 131 in the planarization layer 130. The first structure 300 is in contact with the touch-control line 120 through the first through hole 131 in the planarization layer 130, so as to easily achieve the electrical connection between the first structure 300 and the touch-control line 120, facilitating fabrication and reducing costs.

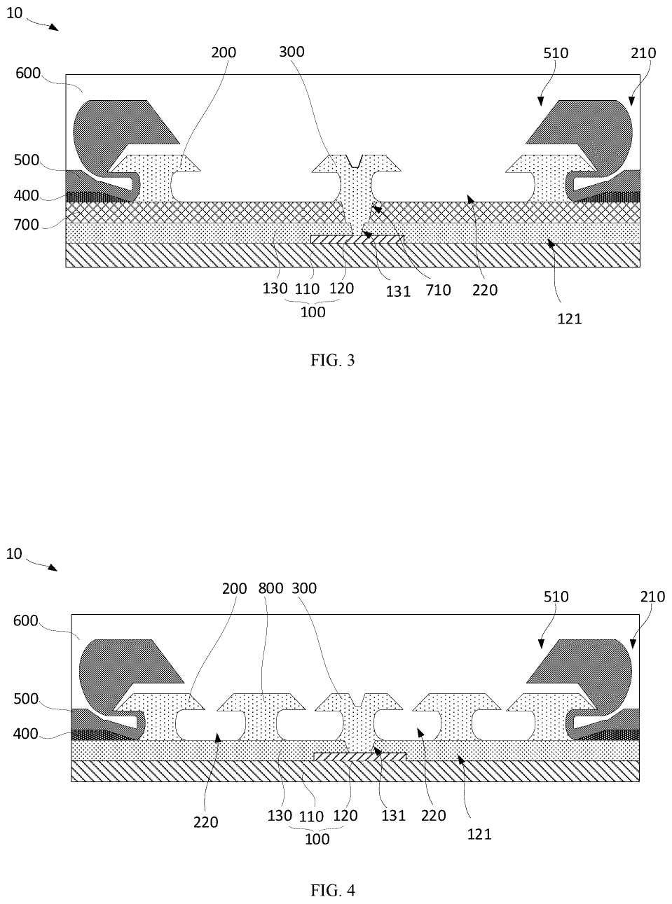

In some embodiments, referring to FIG. 3, the display panel 10 further includes a pixel-defining layer 700. The pixel-defining layer 700 is disposed on the planarization layer 130. The partition structure 200 and the first structure 300 are disposed on the pixel-defining layer 700. The pixel-defining layer 700 includes a second through hole 710, which is aligned with the first through hole 131 to expose the touch-control line 120. The touch-control line 120 exposed from the first through hole 131 and the second through hole 710 are in contact with the first structure 300.

In some embodiments, referring to FIG. 2, a pixel unit 440 comprises adjacent light-emitting structures 400. The at least one first structure 300 includes a plurality of first structures 300, each of which is disposed between adjacent pixel units 440. Specifically, each pixel unit 440 includes the first light-emitting structure 410, the second light-emitting structure 420, and the third light-emitting structure 430. The first light-emitting structure 410 and the second light-emitting structure 420 are arranged side by side along the first direction Y of the first light-emitting structure 410, and the first light-emitting structure 410 and the third light-emitting structure 430 are arranged side by side along the second direction X of the first light-emitting structure 410. The first structure 300 can be disposed between two adjacent third light-emitting structures 430.

In some embodiments, all pixel units 440 have the same structure and are arranged in an array, and the plurality of first structures 300 are also arranged in an array, contributing to a simplified structure of the light-emitting functional layer and facilitating the preparation of the light-emitting structures 400.

In some embodiments, all first structures 300 have the same structure, facilitating the preparation of the first structures 300 and facilitating the touch control.

As such, a large number of first structures 300 can be arranged among adjacent pixel units 440, allowing the precision of touch control to be consistent with the precision of the pixel units 440, thereby improving the precision of the touch control, ensuring the sensitivity of the touch control, and improving the effect of the touch control.

In some embodiments, the touch-control line 120 is Ti/Al/Ti stacked structures, including Ti and Al metal layers stacked by deposition, inkjet printing, coating, etc.

In some embodiments, the at least one touch-control line 120 includes a plurality of touch-control lines 120, and the plurality of touch-control lines 120 define a plurality of touch-control apertures 121 corresponding to the pixel units 440. Each pixel unit 440 corresponds to one touch-control aperture 121, ensuring that the signal of the touch control operation corresponds to the display area of the pixel, allowing the precision of the touch control to be at the level of the size of the pixel unit 440, thereby improving the effect of the touch control.

In some embodiments, the projections of the three partition apertures 210 corresponding to each pixel unit 440 on the planarization layer 130 are located within the projection of the corresponding touch-control aperture 121 on the planarization layer 130, so that the first light-emitting structure 410, the second light-emitting structure 420, and the third light-emitting structure 430 are located within the corresponding touch-control aperture 121. This ensures that the touch-control lines 120 are located in alignment with the partition structure 200, facilitating the preparation of the first structures 300.

In some embodiments, the touch-control lines 120 can form a mesh structure, facilitating the preparation of the touch-control lines 120.

In some embodiments, the plurality of touch-control apertures 121 are independent from each other, and each touch-control aperture 121 forms a ring structure, facilitating the touch control through the touch-control lines 120 and the first structures 300, making the control logic relatively simple and easy to be implemented.

As the touch-control lines 120 are Ti/Al/Ti stacked structures, the electrical resistance of the touch-control lines 120 can be reduced, and the electrical conductivity of the touch-control lines 120 can be improved, thereby reducing the resistance of the touch control, facilitating the transmission of touch control signals, and enhancing the sensitivity of touch-control operations.

In some embodiments, referring to FIG. 2, one first structure 300 is disposed between at least two adjacent pixel units 440. Specifically, one first structure 300 can correspond to two, three, four, or more pixel units 440.

In some embodiments, one first structure 300 is disposed between every two adjacent pixel units 440, so as to form a touch detection point between any two adjacent pixel units 440 by the first structure 300. Two pixel units 440 share one touch detection point, facilitating the touch-control operations.

In some embodiments, one first structure 300 is disposed among every four adjacent pixel units 440, so as to form a touch detection point among any four adjacent pixel units 440 by the first structure 300. Four adjacent pixel units 440 share one touch detection point, facilitating the touch-control operations.

Accordingly, one first structure 300 can be disposed between at least two adjacent pixel units 440, and on the basis of improving the touch-control sensitivity, the first structure 300 can be disposed in the first annular groove 220 of the partition structure 200 between at least two adjacent pixel units 440, thereby facilitating the preparation of the first structure 300.

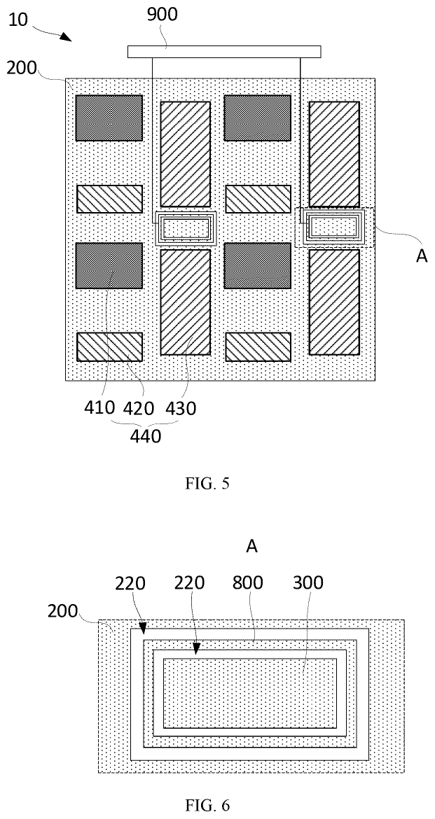

In some embodiments, referring to FIGS. 4, 5, and 6, the display panel 10 further includes a controller 900. Multiple first annular grooves 220 sequentially surround each first structure 300. The first annular groove 220 encircles the protecting ring 800. The protecting ring 800 is electrically insulated from the first structure 300 and the partition structure 200, and the protecting ring 800 is electrically connected to the controller 900. The protecting ring 800 is configured to protect the first structure 300, preventing the first structure 300 from being affected by the cathode electric field formed by the light-emitting structures 400 during touch-control operations.

In some embodiments, the height of the protecting ring 800 on the planarization layer 130 is not greater than or equal to the height of the first structure 300 on the planarization layer 130. Specifically, the height of the protecting ring 800 on the planarization layer 130 can be equal to the height of the first structure 300 on the planarization layer 130 to reduce the thickness of the display panel 10 while ensuring the isolation of the first structure 300 from the cathodes of the light-emitting structures 400. Alternatively, the height of the protective ring 800 on the planarization layer 130 is greater than the height of the first structure 300 on the planarization layer 130 to ensure effective isolation of the first structure 300 from the cathodes of the light-emitting structures 400.

In some embodiments, the touch-control lines 120 are electrically connected to the controller 900, such that independent controls of the protecting rings 800 and the first structures 300 can be performed respectively through the controller 900, and the control logic is relatively simple and easy to be implemented.

As the protecting ring 800 is arranged between the partition structure 200 and the first structure 300, the first structure 300 can be separated from the light-emitting structures 400 in the partition apertures 210, reducing the influence of the cathode electric fields of the light-emitting structures 400 on the first structure 300. This ensures a relatively large self-capacitance between the user's finger and the first structure 300 during touch, and ensures that the capacitance of the first structure 300 is oriented upward, resulting in relatively high touch-control sensitivity and good touch-control performance.

In some embodiments, referring to FIGS. 4, 5, and 6, the first structure 300 is received in at least one protecting ring 800. Specifically, there is one protecting ring 800 around each first structure 300, facilitating the preparation of the display panel 10. Alternatively, there are multiple protecting rings 800 around each first structure 300, improving the isolation of the first structure 300 from the cathodes of the light-emitting structures 400.

In some embodiments, the number of the protecting rings 800 matches the number of the first structures 300, and the protecting rings 800 and the first structures 300 are arranged in one-to-one correspondence, ensuring that all first structures 300 are isolated from the cathodes of the light-emitting structures 400.

By controlling the number of protecting rings 800, the influence of the cathode electric field of the light-emitting structures 400 on the first structures 300 can be adjusted, further reducing the influence of the cathode electric field of the light-emitting structures 400 on the first structures 300, decreasing the self-capacitance formed between the light-emitting structures 400 and the first structures 300, thereby enhancing the touch-control sensitivity.

In some embodiments, the protecting rings 800 include a conductive material.

Specifically, a portion of the protecting rings 800 can be made of the conductive material for saving the conductive material. Alternatively, the protecting rings 800 can be entirely made of the conductive material for facilitating the preparation.

In some embodiments, the protecting rings 800 are made of metal. The metal can have a low electrical resistance.

In some embodiments, the material of the protecting rings 800 can be copper, silver, gold, molybdenum, aluminum, titanium, or any combination thereof.

In some embodiments, the material of the protecting rings 800 is the same as that of the first structures 300, facilitating simultaneous preparation of both the protecting rings 800 and the first structures 300 and ensuring effective isolation of the first structures 300 from the cathodes of the light-emitting structures 400.

Accordingly, the first structures 300 can be effectively isolated from the cathodes of the light-emitting structures 400 simply by arranging the protecting rings 800 including the conductive material between the first structures 300 and the light-emitting structures 400, which facilitates the arrangement of the protecting rings 800.

In some embodiments, referring to FIGS. 1, 3, and 4, at least one of the partition structure 200, the first structures 300, and the protecting rings 800 are formed in a single mask etching step. Specifically, the partition structure 200 and the first structures 300 are formed in a single mask etching step, or the partition structure 200 and the protecting rings 800 are formed in a single mask etching step.

In some embodiments, the partition structure 200, the first structures 300, and the protecting rings 800 are formed in a single mask etching step.

As at least one of the partition structure 200, the first structures 300, and the protecting rings 800 are formed in a single mask etching step, the preparation of the display panel 10 is facilitated, the number of etching steps is reduced, and the mask etching costs are saved, thereby reducing the manufacturing costs.

In some embodiments, referring to FIGS. 1, 3, and 4, the partition structure 200 includes a spacing portion 230 and a blocking portion 240. The spacing portion 230 is located at a side of the blocking portion 240 away from the planarization layer 130. The projection of the spacing portion 230 on the planarization layer 130 covers the projection of the blocking portion 240 on the planarization layer 130. As such, the light-emitting layers of adjacent light-emitting structures 400 are separated by the blocking portion 240, and the cathodes of adjacent light-emitting structures 400 are separated by the spacing portion 230.

In some embodiments, a cross-section of the partition structure 200 is T-shaped or trapezoidal. Alternatively, the cross-section of the partition structure 200 can be in a combination of a T-shape and a trapezoidal shape.

Accordingly, while forming the first structures 300 as touch-control structures, the partition structure 200 is also improved to have a specific shape for further improving the isolation effect of the partition structure 200 on adjacent light-emitting structures 400

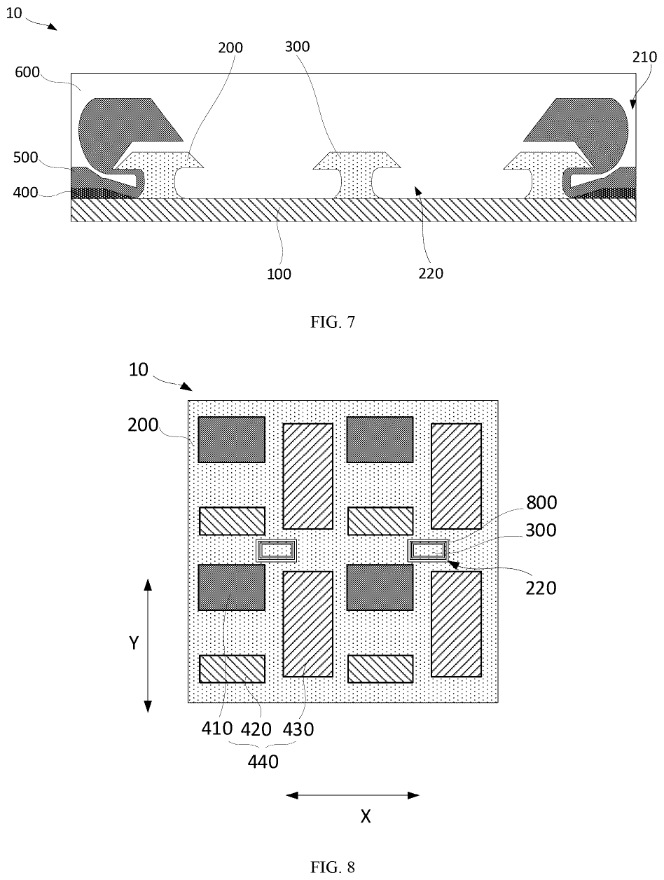

In a second aspect, referring to FIG. 7, an embodiment of the present application provides a display panel 10. The display panel 10 includes a substrate 100, a partition structure 200, at least one first structure 300, and a light-emitting functional layer. The light-emitting functional layer is disposed on a side of the substrate 100. The light-emitting functional layer includes a plurality of light-emitting structures 400. The partition structure 200 is disposed on a side of the structure 200. The partition structure 200 defines a plurality of partition apertures 210 and a plurality of first annular grooves 220. The first structure 300 is disposed within the first annular groove 220. The first structure 300 is configured to be electrically connected to a touch-control signal. The first structure 300 is electrically insulated from the partition structure 200. The partition structure 200 separates adjacent light-emitting structures 400. The light-emitting structures 400 are disposed within the partition apertures 210 and are in one-to-one correspondence with the partition apertures 210.

In some embodiments, the substrate 100 further includes an array substrate. The array substrate includes a driving circuit array, which is electrically connected to the anode for controlling the driving voltage applied between the anode and cathode of the light-emitting structure 400, allowing the light-emitting structure 400 to emit light, and allowing the display panel 10 to perform the display function. In the display panel 10, the partition structure 200, the first structure 300, the light-emitting structures 400, the first encapsulation layer 500, and the second encapsulation layer 600 are the same as those described above in the first aspect respectively and are not repeated herein.

In the display panel 10 provided by the embodiments of the present application, the partition structure 200 defines the first annular grooves 220, the first structure 300 is disposed within the first annular groove 220, and the first structure 300 is electrically insulated from the partition structure 200 and electrically connected to a touch-control signal. As such, the partition structure 200 and the first structure 300 can be fabricated in a single mask etching step, and the first structure 300 can function as a touch-control structure. Thus, the in-cell self-capacitance touch-control can be achieved by the user touching the area where the first structure 300 is located, thereby allowing signal to be transmitted through the first structure 300. Accordingly, the in-cell self-capacitance touch-control can be realized through the first structure 300 without a separate touch-control layer, reducing the manufacturing costs and the thickness of the display panel 10. Moreover, the light-emitting structures 400 are located within the partition apertures 210, and the partition apertures 210 and the first annular grooves 220 are defined by the partition structure 200, therefore the presence of the first structure 300 does not affect the pixel aperture ratio of the display panel 10, ensuring the display performance.

In the embodiments of the present application, the preparation of the partition structure 200 and the first structure 300 can be integrated in one mask etching step and in the same layer. The first structure 300 is electrically connected to the touch-control signal to realize touch-control operation. The partition structure 200 defines the partition apertures 210 for separating adjacent light-emitting structures 400. Therefore, the number of layers in the touch-control display panel 10 is reduced, and the product thickness is reduced. Additionally, the partition apertures 210 ensure the area of the light-emitting structures 400, thereby ensuring the pixel aperture ratio of the display panel 10.

In some embodiments, referring to FIG. 8, a pixel unit 440 comprises three adjacent light-emitting structures 400. The first structure 300 is disposed between adjacent pixel units 440. Specifically, in the pixel unit 440, the first light-emitting structure 410 and the second light-emitting structure 420 are arranged side by side along the first direction Y of the first light-emitting structure 410, and the first light-emitting structure 410 and the third light-emitting structure 430 are arranged side by side along the second direction X of the first light-emitting structure 410. The first structure 300 can be disposed between two adjacent third light-emitting structures 430.

In some embodiments, the at least one first structure 300 includes a plurality of first structures 300, and one first structure 300 is disposed between two adjacent pixel units 440 and forms a touch detection point between two adjacent pixel units 440 by the first structure 300. Two pixel units 440 share one touch detection point, facilitating the touch-control operations.

In some embodiments, one first structure 300 is disposed among four adjacent pixel units 440, so as to form a touch detection point among four adjacent pixel units 440 by the first structure 300. Four adjacent pixel units 440 share one touch detection point, facilitating the touch-control operations.

As such, a large number of first structures 300 can be arranged among adjacent pixel units 440, allowing the precision of touch control to be consistent with the precision of the pixel units 440, thereby improving the precision of the touch control, ensuring the sensitivity of the touch control, and improving the effect of the touch control.

In some embodiments, referring to FIG. 8, a plurality of first annular grooves 220 are successively arranged around each first structure 300. The first annular groove 220 encircles a protecting ring 800. The protecting ring 800 is configured to be electrically connected to a protecting signal. The protecting ring 800 is disposed around the first structure 300, and is electrically insulated from the first structure 300 and the partition structure 200. The protecting ring 800 is configured to isolate the first structure 300 from the cathode electric field of the light-emitting structures 400.

In some embodiments, the height of the protecting ring 800 on the planarization layer 130 is not less than the height of the first structure 300 on the planarization layer 130 to ensure effective isolation of the first structure 300 from the cathodes of the light-emitting structures 400.

As the first structures 300 are separated from the partition structure 200 by the protecting rings 800, the cathode electric fields formed by the light-emitting structures 400 in the partition apertures 210 can be separated from the capacitances formed by the first structures 300, reducing the influence of the cathode electric fields of the light-emitting structures 400 on the first structures 300. This ensures a relatively large self-capacitance between the user's finger and the first structure 300 during touch, and ensures that the capacitance of the first structure 300 is oriented upward, resulting in relatively high touch-control sensitivity and good touch-control performance.

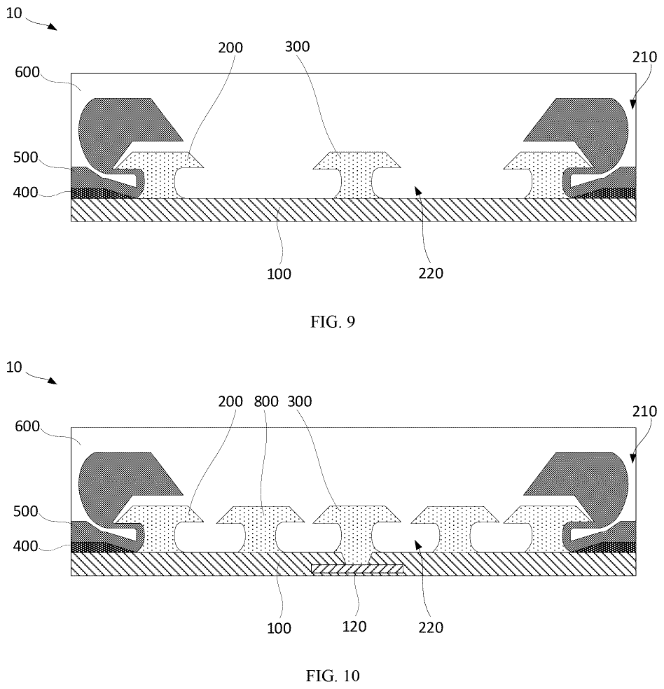

In a third aspect, referring to FIG. 9, an embodiment of the present application provides a display panel 10. The display panel 10 includes a substrate 100, a partition functional layer, and a light-emitting functional layer. The partition functional layer is disposed on a side of the substrate 100. The partition functional layer includes a plurality of first annular grooves 220, a partition structure 200, and at least one first structure 300. The partition structure 200 and the first structure 300 are located at opposite sides of the first annular groove 220. The partition structure 200 defines a plurality of partition apertures 210. The first structure 300 is disposed within the first annular groove 220. The first structure 300 is configured to be electrically connected to a touch-control signal. The first structure 300 is electrically insulated from the partition structure 200. The light-emitting functional layer is disposed on the side of the substrate 100. The light-emitting functional layer includes a plurality of light-emitting structures 400. The light-emitting structures 400 are disposed within the partition apertures 210 and are in one-to-one correspondence with the partition apertures 210.

In some embodiments, the substrate 100 further includes an array substrate. The array substrate includes a driving circuit array, which is electrically connected to the anode for controlling the driving voltage applied between the anode and cathode of the light-emitting structure 400, allowing the light-emitting structure 400 to emit light, and allowing the display panel 10 to perform the display function. In the display panel 10, the partition structure 200, the first structure 300, the light-emitting structures 400, the first encapsulation layer 500, and the second encapsulation layer 600 are the same as those described above in the first aspect respectively and are not repeated herein.

In the display panel 10 provided by the embodiments of the present application, the partition functional layer is partitioned into the first structure 300 and the partition structure 200 by the first annular groove 220, the partition structure 200 defines the first annular groove 220, the first structure 300 is disposed within the first annular groove 220, and the first structure 300 is electrically insulated from the partition structure 200 and electrically connected to the touch-control signal. As such, the partition structure 200 and the first structure 300 can be fabricated in a single mask etching step, and the first structure 300 can function as a touch-control structure. Thus, the in-cell self-capacitance touch-control can be achieved by the user touching the area where the first structure 300 is located, thereby allowing a signal to be transmitted through the first structure 300. Accordingly, the in-cell self-capacitance touch-control can be realized through the first structure 300 without a separate touch-control layer, reducing the manufacturing costs and the thickness of the display panel 10. Moreover, as the light-emitting structures 400 are located within the partition apertures 210, the presence of the first structure 300 does not affect the pixel aperture ratio of the display panel 10, ensuring the display performance.

In the embodiments of the present application, the partition functional layer is formed in one mask etching step. The partition functional layer is partitioned into the first structure 300 and the partition structure 200 by the first annular groove 220. The first structure 300 is electrically connected to the touch-control signal to realize touch-control operation. The partition structure 200 defines the partition apertures 210 for separating adjacent light-emitting structures 400. Therefore, the number of layers in the touch-control display panel 10 is reduced, and the product thickness is reduced. Additionally, the partition apertures 210 ensure the area of the light-emitting structures 400, thereby ensuring the pixel aperture ratio of the display panel 10.

In some embodiments, as shown in FIG. 9, the partition structure 200 and the first structure 300 are formed in the same layer.

In some embodiments, the partition structure 200 and the first structure 300 are formed in a single mask etching step.

The partition structure 200 and the first structure 300 are formed in the same layer, which ensures that the thickness of the partition functional layer is uniform overall and relatively small, thereby achieving a display panel 10 with a small thickness, facilitating the preparation of the partition functional layer.

In a fourth aspect, referring to FIG. 10, an embodiment of the present application provides a display panel 10. The display panel 10 includes a substrate 100, a partition structure 200, at least one first structure 300, at least one protecting ring 800, and a light-emitting functional layer. The partition structure 200 is disposed on a side of the partition structure 200. The partition structure 200 defines a plurality of partition apertures 210 and a plurality of first annular grooves 220. The first annular groove 220 encircles the first structure 300 and the protecting ring 800. The first structure 300 is configured to be electrically connected to a touch-control signal. The protecting ring 800 is configured to be electrically connected to a protecting signal. Each protecting ring 800 is disposed around one first structure 300, and is spaced from the first structure 300. The protecting ring 800 is electrically insulated from the first structure 300 and the partition structure 200. The light-emitting functional layer is disposed on the side of the substrate 100. The light-emitting functional layer includes a plurality of light-emitting structures 400. The partition structure 200 separates adjacent light-emitting structures 400. The light-emitting structures 400 are disposed within the partition apertures 210 and are in one-to-one correspondence with the partition apertures 210.

In some embodiments, the substrate 100 further includes an array substrate. The array substrate includes a driving circuit array, which is electrically connected to the anode for controlling the driving voltage applied between the anode and cathode of the light-emitting structure 400, allowing the light-emitting structure 400 to emit light, and allowing the display panel 10 to perform the display function. In the display panel 10, the partition structure 200, the first structure 300, the light-emitting structures 400, the first encapsulation layer 500, and the second encapsulation layer 600 are the same as those described above in the first aspect respectively and are not repeated herein.

In the display panel 10 provided by the embodiments of the present application, the partition structure 200 defines the first annular grooves 220, the first annular groove 220 encircles the first structure 300 and the protecting ring 800, the first structure 300 is electrically insulated from the partition structure 200 and the protecting ring 800 and electrically connected to a touch-control signal, and the protecting ring 800 is electrically connected to a protecting signal. As such, the partition structure 200, the first structure 300, and the protecting ring 800 can be fabricated in a single mask etching step, the first structure 300 can function as a touch-control structure, and the protecting ring 800 can function as a protecting structure. Thus, the in-cell self-capacitance touch-control can be achieved by the user touching the area where the first structure 300 is located, thereby allowing a signal to be transmitted through the first structure 300. Accordingly, the in-cell self-capacitance touch-control can be realized through the first structure 300 without a separate touch-control layer, reducing the manufacturing costs and the thickness of the display panel 10. Moreover, the light-emitting structures 400 are located within the partition apertures 210, and the partition apertures 210 and the first annular grooves 220 are defined by the partition structure 200, therefore the presence of the first structure 300 does not affect the pixel aperture ratio of the display panel 10, ensuring the display performance. In addition, the protecting ring 800 can reduce the influence of the cathode electric field of the light-emitting structures 400 on the first structure 300, thus improving the sensitivity of the touch control.

In the embodiments of the present application, the preparation of the partition structure 200, the first structure 300, and the protecting ring 800 can be integrated in one mask etching step and in the same layer. The first structure 300 is electrically connected to a touch-control signal to realize touch-control operation. The partition structure 200 defines partition apertures 210 for separating adjacent light-emitting structures 400. The protecting ring 800 functions for isolation and protection through protecting signals. Therefore, the number of layers in the touch-control display panel 10 is reduced, and the product thickness is reduced. Additionally, the partition apertures 210 ensure the area of the light-emitting structures 400, thereby ensuring the pixel aperture ratio of the display panel 10.

In some embodiments, referring to FIG. 10, the substrate 100 further includes at least one touch-control line 120, and the display panel 10 further includes a controller 900. The first structure 300 is electrically connected to the touch-control line 120 through a first through hole 131. The protecting ring 800 is electrically connected to the controller 900.

In some embodiments, the touch-control line 120 is electrically connected to the controller 900, such that independent control of the protecting ring 800 and the first structure 300 can be performed respectively through the controller 900 easily.

The touch-control signal is transmitted to the first structure 300 through the touch-control line 120, and the protecting signal is transmitted to the protecting ring 800 from the controller 900. Thus, the touch-control signal is transmitted between the first structure 300 and the touch-control line 120, and the protecting signal is transmitted between the protecting ring 800 and the controller 900, thereby reducing the signal paths, and facilitating signal input of the first structure 300 and the protecting ring 800.

In some embodiments, the partition structure 200, the first structure 300, and the protecting ring 800 each include an electrical conductive material. Specifically, the partition structure 200, the first structure 300, and the protecting ring 800 each can be partially or entirely made of the electrical conductive material.

In some embodiments, the electrical conductive material is a metal material with relatively low resistance.

In some embodiments, the electrical conductive material can be selected from the group consisting of copper, silver, gold, molybdenum, aluminum, titanium, and any combination thereof.

In some embodiments, the materials of the partition structure 200, the first structure 300, and the protecting ring 800 are the same, facilitating simultaneous fabrication of the partition structure 200, the first structure 300, and the protecting ring 800 in the same layer.

The partition structure 200, the first structure 300, and the protecting ring 800 each including the electrical conductive material are all electrical conducting structures, thus enabling the cathode signals for the light-emitting structures 400, the touch-control signal, and the protecting signal to be inputted respectively.

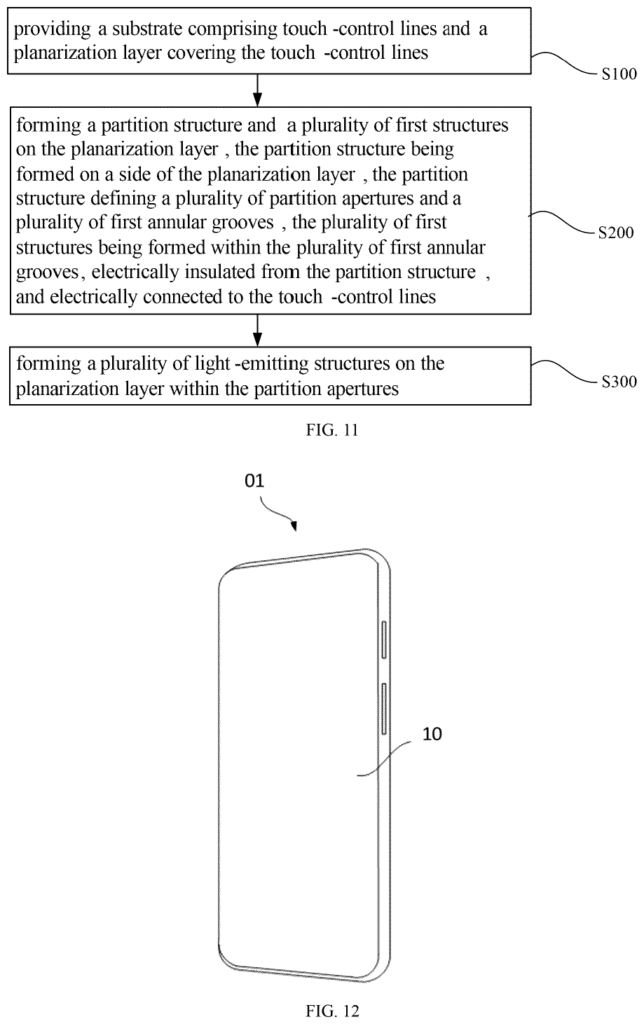

In a fifth aspect, referring to FIG. 11, an embodiment of the present application provides a method for preparing a display panel, including follow steps S100 to S300.

In S100, a substrate is provided. The substrate includes at least one touch-control line and a planarization layer covering the touch-control line. Exemplarily, the substrate can be a stacked structure including an array substrate, the touch-control line, and the planarization layer. A pixel-defining layer is formed on the substrate.

In S200, a partition structure and at least one first structure are formed on the planarization layer. The partition structure is formed on a side of the planarization layer, and the partition structure defines a plurality of partition apertures and a plurality of first annular grooves. The first structure is formed within the first annular groove, electrically insulated from the partition structure, and electrically connected to the touch-control line. Exemplarily, a layer of partition material is deposited on the planarization layer or on the pixel-defining layer, and etched to form the partition structure and the first structure in one mask etching step.

In S300, a plurality of light-emitting structures are formed on the planarization layer, and the light-emitting structures are formed within the partition apertures. Exemplarily, forming the light-emitting structures involves: sequentially depositing a first conductive material layer, a light-emitting material layer, a second conductive material layer, and an encapsulation material layer on the entire side of the planarization layer; patterning the deposited layers to form a plurality of first light-emitting structures and a plurality of first encapsulation films; repeating the above steps to respectively form a plurality of second light-emitting structures and a plurality of second encapsulation films, and a plurality of third light-emitting structures and a plurality of third encapsulation films; the first, second, and third encapsulation films form a first encapsulation layer; subsequently, depositing a second encapsulation layer on the entire side of the planarization layer, wherein the second encapsulation layer and the first encapsulation layer encapsulates the display panel.

In the method for preparing the display panel provided by the embodiments of the present application, the partition structure defines the first annular grooves, the first structure is formed within the first annular groove, and the first structure is electrically insulated from the partition structure and electrically connected to the touch-control line. As such, the partition structure and the first structure can be fabricated in a single mask etching step, and the first structure can function as a touch-control structure. Thus, an in-cell self-capacitance touch-control can be achieved by the user touching the area where the first structure is located, thereby allowing a signal to be transmitted through the touch-control line. Accordingly, the in-cell self-capacitance touch-control can be realized through the first structure without a separate touch-control layer, reducing the manufacturing costs and the thickness of the display panel. Moreover, the light-emitting structures are formed within the partition apertures, and the partition apertures, and the first annular grooves are defined by the partition structure, therefore the presence of the first structure does not affect the pixel aperture ratio of the display panel, ensuring the display performance.

It should be understood that, though the steps in the flow charts involved in the above embodiments are shown sequentially as indicated by the arrows, these steps are not necessarily executed sequentially in the order indicated by the arrows. Unless otherwise specified herein, the sequence of the steps is not strictly limited, and the steps may be performed in other orders. Moreover, at least some of the steps in the flow charts involved in the above embodiments can include multiple sub-steps or multiple stages, these sub-steps or stages are not necessarily performed at the same time, but may be performed at different times. These sub-steps or stages are not necessarily to be sequentially performed, but can be performed alternately or in turn with at least some of the sub-steps or stages of other steps.

In a sixth aspect, referring to FIG. 12, an embodiment of the present application provides a display device 01, including the display panel 10 in any one of the above described embodiments.

The display device 01 can be a mobile or fixed terminal, such as a smartphone, a television, a tablet computer, a laptop, an ultra-mobile personal computer (UMPC), a personal digital assistant (PDA), a navigation device, a smart watch, a virtual reality device, etc., equipped with the display panel 10.

In the display device provided by the embodiments of the present application, the partition structure defines the first annular grooves, the first structure is formed within the first annular groove, and the first structure is electrically insulated from the partition structure and electrically connected to the touch-control line. As such, the partition structure and the first structure can be fabricated in a single mask etching step, and the first structure can function as a touch-control structure. Thus, an in-cell self-capacitance touch-control can be achieved by the user touching the area where the first structure is located, thereby allowing a signal to be transmitted through the touch-control line. Accordingly, the in-cell self-capacitance touch-control can be realized through the first structure without a separate touch-control layer, reducing the manufacturing costs and the thickness of the display panel. Moreover, the light-emitting structures are formed within the partition apertures, and the partition apertures and the first annular grooves are defined by the partition structure, therefore the presence of the first structure does not affect the pixel aperture ratio of the display panel, thus ensuring the display performance.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present application.

The above-described embodiments are only several implementations of the present application, and the descriptions are relatively specific and detailed, but they should not be construed as limiting the scope of the present application. It should be understood by those of ordinary skill in the art that various modifications and improvements can be made without departing from the concept of the present application, and all these modifications and improvements fall within the protection scope of the present application. Therefore, the patent protection of the present application shall be defined by the appended claims.

What is claimed is:

1. A display panel, comprising:
a substrate, comprising at least one touch-control line and a planarization layer covering the touch-control line;
a partition structure, disposed on a side of the planarization layer, the partition structure defining a plurality of partition apertures and a plurality of first annular grooves;
at least one first structure disposed within at least one of the plurality of first annular grooves, the first structure being electrically insulated from the partition structure and electrically connected to the touch-control line; and
a light-emitting functional layer disposed on the side of the planarization layer, the light-emitting functional layer comprising a plurality of light-emitting structures disposed within the plurality of partition apertures.

2. The display panel according to claim 1, wherein the planarization layer comprises a plurality of first through holes,
at least one of the plurality of first through holes extends through the planarization layer, and exposes the touch-control line; and
the first structure is in contact with the touch-control line exposed from the at least one of the plurality of first through holes.

3. The display panel according to claim 1, wherein the plurality of light-emitting structures form a plurality of pixel units, at least one of the pixel units comprises a plurality of adjacent light-emitting structures, the first structure is disposed between adjacent pixel units, and a plurality of first structures are arranged in an array.

4. The display panel according to claim 3, wherein the touch-control line comprises a Ti, Al, and Ti stacked structure, and the at least one touch-control line comprises a plurality of touch-control lines, the touch-control lines define a plurality of touch-control apertures corresponding to the pixel units.

5. The display panel according to claim 4, wherein projections of three partition apertures corresponding to the pixel unit on the planarization layer are located within a projection of a corresponding touch-control aperture on the planarization layer.

6. The display panel according to claim 4, wherein the plurality of touch-control apertures are independent from each other, and each touch-control aperture is formed in a ring structure.

7. The display panel according to claim 3, wherein the at least one first structure comprises a plurality of first structures, the first structure is disposed between at least two adjacent pixel units.

8. The display panel according to claim 1, further comprising a controller and at least one protecting ring; wherein:
more than one of the plurality of first annular grooves sequentially surround the first structure, the first annular groove encircles the protecting ring; and
the protecting ring encircles the first structure, the protecting ring is electrically insulated from the first structure and the partition structure, and the protecting ring is electrically connected to the controller.

9. The display panel according to claim 8, wherein a height of the protecting ring from the planarization layer is greater than or equal to a height of the first structure on the planarization layer.

10. The display panel according to claim 8, wherein the at least one protecting ring comprises a plurality of protecting rings, and the first structure is received in at least one of the plurality of protecting rings; and
the at least one protecting ring comprises a conductive material.

11. The display panel according to claim 8, wherein the partition structure, the at least one first structure and the protecting ring are located in a same layer.

12. The display panel according to claim 1, wherein the partition structure comprises a spacing portion and a blocking portion, the spacing portion is located at a side of the blocking portion away from the planarization layer, and a projection of the spacing portion on the planarization layer covers a projection of the blocking portion on the planarization layer.

13. A display panel, comprising:
a substrate;
a light-emitting functional layer disposed on a side of the substrate, the light-emitting functional layer comprising a plurality of light-emitting structures;
a partition structure disposed on the side of the substrate, the partition structure defining a plurality of partition apertures and a plurality of first annular grooves; and
at least one first structure disposed within at least one of the plurality of first annular grooves, the first structure being configured to be electrically connected to a touch-control signal and electrically insulated from the partition structure;
wherein the partition structure separates adjacent light-emitting structures, and the plurality of light-emitting structures are disposed within the plurality of partition apertures.

14. The display panel according to claim 13, wherein the plurality of light-emitting structures form a plurality of pixel units, at least one of the pixel units comprising three adjacent light-emitting structures, and the first structure is disposed between adjacent pixel units.

15. The display panel according to claim 13, further comprising at least one protecting ring; wherein:
more than one of the plurality of first annular grooves sequentially surround the first structure, the first annular groove encircling the protecting ring; and
the protecting ring is configured to be electrically connected to a protecting signal and is disposed around the first structure, and the protecting ring is electrically insulated from the first structure and the partition structure.

16. A display panel, comprising:
a substrate;
a partition functional layer disposed on a side of the substrate, the partition functional layer comprising a plurality of first annular grooves, a partition structure, and at least one first structure, the partition structure and the first structure being located at opposite sides of the first annular groove, the partition structure defining a plurality of partition apertures, the at least one first structure being disposed within at least one of the plurality of first annular grooves, and configured to be electrically connected to a touch-control signal and electrically insulated from the partition structure; and
a light-emitting functional layer disposed on the side of the substrate, the light-emitting functional layer comprising a plurality of light-emitting structures disposed within the plurality of partition apertures.

17. The display panel according to claim 16, wherein the partition structure and the first structure are disposed in a same layer.

18. The display panel according to claim 16, wherein the partition functional layer further comprises a protecting ring, the protecting ring is disposed around and spaced from the first structure, and the protecting ring is configured to be electrically connected to a protecting signal.

19. The display panel according to claim 18, further comprising a controller;
wherein the substrate further comprises a touch-control line, the first structure is electrically connected to the touch-control line through a corresponding first through hole, the protecting ring is electrically connected to the controller.

20. The display panel according to claim 19, wherein the partition structure, the first structure, and the protecting ring respectively comprises an electrical conductive material.
